(19) United States
(12) Patent Application Publication
(10) Pub. No.: US 2025/0142894 A1
(43) Pub. Date: May 1, 2025

(54) SEMICONDUCTOR DEVICE AND METHOD OF MANUFACTURING THE SAME

(71) Applicant: Samsung Electronics Co., Ltd., Suwon-si (KR)

(72) Inventors: Huije RYU, Suwon-si (KR); Junyoung KWON, Suwon-si (KR); Changhyun KIM, Suwon-si (KR); Minsu SEOL, Suwon-si (KR)

(73) Assignee: Samsung Electronics Co., Ltd., Suwon-si (KR)

(21) Appl. No.: 18/752,024

(22) Filed: Jun. 24, 2024

(30) Foreign Application Priority Data
Nov. 1, 2023 (KR) 10-2023-0149354

(51) Int. Cl. H01L 29/786; H01L 21/3115; H01L 29/423; H01L 29/66; H01L 29/775

(52) U.S. Cl. CPC H10D 30/6757; H01L 21/31155; H10D 30/014; H10D 30/43; H10D 30/6735

(57) ABSTRACT

A semiconductor device may include a two-dimensional (2D) material layer extending in a first direction, a source electrode and a drain electrode each electrically connected to the 2D material layer, an insulating layer arranged on the 2D material layer, and a gate electrode arranged apart from the 2D material layer in a second direction perpendicular to the first direction, wherein the insulating layer includes a dopant.

### CROSS-REFERENCE TO RELATED APPLICATION

This application is based on and claims priority under 35 U.S.C. § 119 to Korean Patent Application No. 10-2023-0149354, filed on Nov. 1, 2023, in the Korean Intellectual Property Office, the disclosure of which is incorporated by reference herein in its entirety.

### BACKGROUND

### 1. Field

The disclosure relates to semiconductor devices and methods of manufacturing the same.

### 2. Description of the Related Art

As miniaturization is underway to improve the integration of semiconductor devices, performance limitations due to the scaling of three-dimensional (3D) bulk materials have appeared. Thus, research has been conducted on semiconductor devices based on two-dimensional (2D) semiconductor materials to overcome these limitations.

In a 2D semiconductor material-based semiconductor device, it is essential to control the doping level of a 2D semiconductor material channel. To this end, various approaches, such as controlling the composition of a 2D semiconductor material channel or changing the phase, have been attempted, but there is a limit in which it is difficult to physically access the 2D semiconductor material channel under an insulating layer.

### SUMMARY

According to the disclosure, provided are semiconductor devices including a two-dimensional (2D) semiconductor material and methods of manufacturing the same.

Additional aspects will be set forth in part in the description which follows and, in part, will be apparent from the description, or may be learned by practice of the presented example embodiments of the disclosure.

According to an example embodiment, a semiconductor device may include a two-dimensional (2D) material layer extending in a first direction, a source electrode and a drain electrode each electrically connected to the 2D material layer, an insulating layer on the 2D material layer, and a gate electrode being apart from the 2D material layer in a second direction perpendicular to the first direction, wherein the insulating layer includes a dopant.

The dopant may be present in both edge regions of the insulating layer that do not overlap the gate electrode in the second direction.

The dopant may include P⁺, As⁺, B⁻, Al₋, or H⁺.

The insulating layer may include traps.

The traps may be present in both edge regions of the insulating layer that do not overlap the gate electrode in the second direction.

A region of the 2D material layer overlapping the gate electrode in the second direction may operate as a channel.

A region of the 2D material layer overlapping the gate electrode in the second direction may exhibit semiconductor characteristics.

An edge region of the 2D material layer that does not overlap the gate electrode in the second direction may exhibit metal characteristics.

The 2D material layer may include graphene, transition metal dichalcogenide (TMD), or black phosphorus.

The dopant may be uniformly present in an entire region of the insulating layer. The insulating layer may include metal oxide.

The metal oxide may include Si, Al, La, Ti, Zr, Hf, Mg, Ge, Y, Lu, or Sr.

The 2D material layer may include a plurality of layers.

The gate electrode may include metal, conductive nitride, or conductive oxide.

A width of the gate electrode may be about 10 nm to about 100 nm.

The semiconductor device may be a field effect transistor.

According to an example embodiment, a method of manufacturing a semiconductor device may include forming a two-dimensional (2D) material layer extending in a first direction on a substrate, forming a source electrode and a drain electrode on edges of the substrate, forming an insulating layer on the 2D material layer, and implanting a dopant into the insulating layer.

The method for manufacturing a semiconductor device may further include forming a gate electrode on the insulating layer before the dopant is implanted into the insulating layer, wherein the dopant may be implanted into the insulating layer by using the gate electrode as a mask.

The method of manufacturing a semiconductor device may further include forming a gate electrode on the insulating layer after the dopant has been implanted into the insulating layer.

The method of manufacturing a semiconductor device may further include annealing the insulating layer after the dopant has been implanted into the insulating layer.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a cross-sectional view illustrating a semiconductor device according to an example embodiment;

FIG. 2 is a cross-sectional view illustrating a semiconductor device according to another example embodiment;

FIG. 3 is a cross-sectional view illustrating a semiconductor device according to another example embodiment;

FIG. 4 is a cross-sectional view illustrating a semiconductor device according to another example embodiment;

FIGS. 5A to 5F are cross-sectional views illustrating a method of manufacturing a semiconductor device according to an example embodiment;

FIGS. 6A to 6C are cross-sectional views partially illustrating a method of manufacturing a semiconductor device according to another example embodiment;

FIG. 7 is a perspective view illustrating a semiconductor device according to another example embodiment;

FIG. 8 is a cross-sectional view taken along line A-A′ of FIG. 7; and

FIGS. 9 and 10 are conceptual block diagrams schematically illustrating a device architecture applicable to an electronic device according to an example embodiment.

### DETAILED DESCRIPTION

Reference will now be made in detail to some example embodiments, examples of which are illustrated in the accompanying drawings, wherein like reference numerals refer to like elements throughout. In this regard, the present example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, semiconductor devices and methods of manufacturing the same will be described in detail with reference to the accompanying drawings. In the following drawings, the same reference numerals refer to the same components, and the size of each component in the drawings may be exaggerated for clarity and convenience of description. In addition, embodiments described below are merely illustrative, and various modifications are possible from these example embodiments.

Hereinafter, spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly. Thus, the term “upper portion” or “on” may also include “to be present above on a non-contact basis” as well as “to be on the top portion in directly contact with”. The singular expression includes plural expressions unless the context clearly implies otherwise. In addition, when a part “includes” a component, this means that it may further include other components, not excluding other components unless defined otherwise.

The use of the term “the” and similar indicative terms may correspond to both singularity and plurality. Unless there is a clear order or contrary description of the steps constituting the method, these steps may be performed in the appropriate order, and are not necessarily limited to the order described.

The connection or connection members of lines between the components shown in the drawings exemplarily represent functional connection and/or physical or circuit connections, and may be replaceable or represented as various additional functional connections, physical connections, or circuit connections in an actual device.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

The use of all examples or illustrative terms is simply to describe technical ideas in detail, and the scope is not limited due to these examples or illustrative terms unless the scope is limited by the claims.

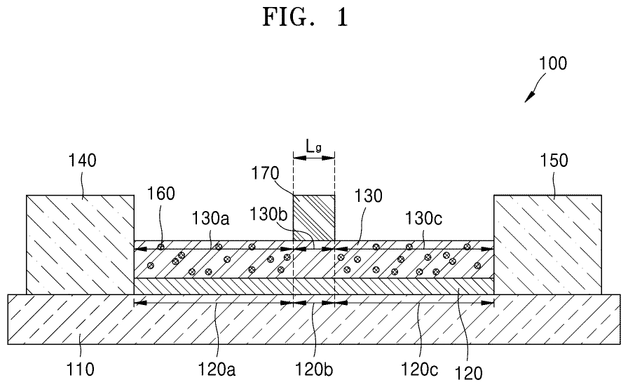

FIG. 1 is a cross-sectional view illustrating a semiconductor device according to an example embodiment.

Referring to FIG. 1, a semiconductor device 100 may include a substrate 110, a two-dimensional (2D) material layer 120 arranged on the substrate 110, and extending in a first direction, a source electrode 140 and a drain electrode 150 electrically connected to the 2D material layer 120, an insulating layer 130 arranged on the 2D material layer 120, and a gate electrode 170 arranged vertically spaced apart from the 2D material layer in a second direction perpendicular to the first direction.

The substrate 110 may include a semiconductor material. The substrate 110 may include, for example, silicon (Si), germanium (Ge), silicon germanium (SiGe), silicon carbide (SiC), gallium arsenic (GaAs), indium arsenic (InAs), indium phosphide (InP), and the like. In addition, the substrate 110 may include an insulating material such as oxide, silicon nitride, or silicon oxynitride. The substrate 110 may be a substrate for growing the 2D material layer 120.

The 2D material layer 120 may include a 2D semiconductor material. The 2D semiconductor material refers to a 2D material having a layered structure in which constituent atoms are two-dimensionally bonded. The 2D semiconductor material has excellent electrical properties and may maintain high mobility even when the thickness is reduced to nano scale without significantly changing its characteristics.

The 2D material layer 120 may include, for example, graphene, transition metal dichalcogenide (TMD), or black phosphorus. The TMD may include one metal element selected from the group consisting of Mo, W, Nb, V, Ta, Ti, Zr, Hf, Tc, and Re, and one chalcogen element selected from the group consisting of S, Se, and Te. The 2D material layer 120 may include, for example, MoS₂, MoSe₂, MoTe₂, WS₂, WSe₂, MoTe₂, or PtSe₂.

The 2D material layer 120 may include edge regions 120a and 120c and a central region 120b provided between the edge regions 120a and 120c. The central region 120b of the 2D material layer may be located in a center portion of the 2D material layer 120. The edge regions 120a and 120c of the 2D material layer may not overlap the gate electrode 170 in a vertical direction, and the central region 120b of the 2D material layer may overlap the gate electrode 170 in a vertical direction.

The edge regions 120a and 120c of the 2D material layer may be doped at a high concentration to exhibit metal characteristics. The central region 120b of the 2D material layer is not doped and may exhibit semiconductor characteristics. The central region 120b of the 2D material layer may operate as a channel. The central region 120b of the 2D material layer may control on/off of the semiconductor device 100.

The insulating layer 130 may be provided on the 2D material layer 120. The insulating layer 130 may include metal oxide. The metal forming the metal oxide may include at least one of Si, Al, La, Ti, Zr, Hf, Mg, Ge, Y, Lu, and Sr.

The insulating layer 130 may include edge regions 130a and 130c and a central region 130b provided between the edge regions 130a and 130c. The central region 130b of the insulating layer may be located in a central portion of the insulating layer 130. The edge regions 130a and 130c of the insulating layer may not overlap the gate electrode 170 in a vertical direction, and the central region 130b of the insulating layer may overlap the gate electrode 170 in a vertical direction.

The insulating layer 130 may include a dopant. The dopant may be implanted into the insulating layer 130 through an ion implantation process. The dopant may include P⁺, As⁺, B⁻, Al₋, or H⁺. The dopant may be present in the edge regions 130a and 130c of the insulating layer that does not overlap the gate electrode 170 in a vertical direction, and may not be present in the central region 130b of the insulating layer.

The insulating layer 130 may include traps 160. The traps 160 may exist in the edge regions 130a and 130c of the insulating layer that do not overlap the gate electrode 170 in a vertical direction. The traps 160 may have charges therein. Charges in the traps 160 may be diffused into the 2D material layer 120 to cause charge transfer doping.

As ions accelerated through an ion implantation process are implanted into the insulating layer 130, the traps 160 may be generated by breaking of a bonding network of the metal oxide constituting the insulating layer 130. In this case, oxygen released from the metal oxide has free electrons, and as the free electrons diffuse into the 2D material layer 120, the 2D material layer 120 is doped.

The density of the traps 160 may be controlled through an ion implantation acceleration voltage and an implantation time. The doping level of the 2D material layer 120 may be adjusted by controlling the density of the traps 160.

The insulating layer 130 may serve as a passivation layer covering the 2D material layer 120. A thickness of the insulating layer 130 may be, for example, about 1 nm to about 20 nm. A thickness of the insulating layer 130 may be, for example, about 3 nm to about 10 nm.

The source electrode 140 and the drain electrode 150 may be electrically connected to the 2D material layer 120. The source electrode 140 and the drain electrode 150 may have various structures such as an elevated structure and a recessed structure. The source electrode 140 and the drain electrode 150 may include a metal material. The source electrode 140 and the drain electrode 150 may include, for example, a metal material having excellent electrical conductivity, such as Ag, Au, Pt, or Cu.

The gate electrode 170 may include a metal material or a conductive oxide. The metal material may include, for example, Au, Ti, TiN, TaN, W, Mo, WN, Pt, Ni, or a combination thereof. In addition, the conductive oxide may include, for example, Indium Tin Oxide (ITO), Indium Zinc Oxide (IZO), etc. However, this is merely an example.

A width Lg of the gate electrode 170 may be, for example, about 10 nm to about 100 nm. The width Lg of the gate electrode 170 is the same as the width of the central region 120b of the 2D material layer and the central region 130b of the insulating layer.

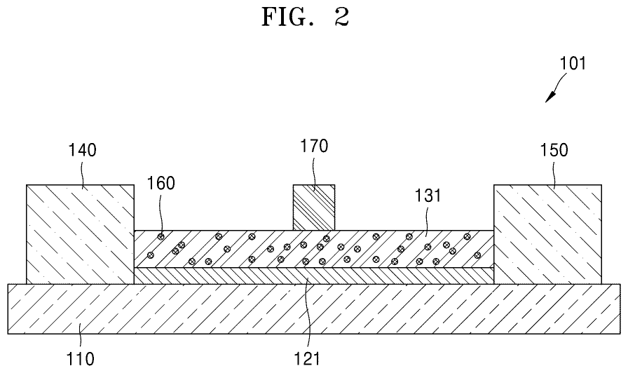

FIG. 2 is a cross-sectional view illustrating a semiconductor device according to another example embodiment.

Referring to FIG. 2, a semiconductor device 101 may include a substrate 110, a two-dimensional (2D) material layer 121 arranged on the substrate 110, and extending in a first direction, a source electrode 140 and a drain electrode 150 electrically connected to the 2D material layer 121, an insulating layer 131 arranged on the 2D material layer 121, and a gate electrode 170 arranged vertically spaced apart from the 2D material layer 121 in a second direction perpendicular to the first direction.

The semiconductor device 101 of FIG. 2 may be the same as the semiconductor device 100 of FIG. 1, except that the 2D material layer 121 and the insulating layer 131 are different from the 2D material layer 120 and the insulating layer 130 of FIG. 1, respectively. In describing FIG. 2, redundant descriptions of FIG. 1 are omitted.

The 2D material layer 121 may be doped from the traps 160 of the insulating layer 131. The 2D material layer 121 may be doped by electric charges moving from the traps 160 of the insulating layer 131. The 2D material layer 121 may be uniformly doped. A threshold voltage of the semiconductor device 101 may be adjusted by adjusting a doping level of the 2D material layer 121.

The insulating layer 131 may include a dopant. The dopant may be implanted into the insulating layer 131 through an ion implantation process. The dopant may include P⁺, As⁺, B⁻, Al₋, or H⁺.

The insulating layer 131 may include edge regions that do not overlap the gate electrode 170 in a vertical direction and a central region that overlaps the gate electrode 170 in a vertical direction. The dopant may be uniformly present in the entire region of the insulating layer 131. The dopant may exist in both edge regions of the insulating layer 131 that does not overlap the gate electrode 170 in a vertical direction and in the central region of the insulating layer 131 that overlaps the gate electrode 170 in a vertical direction.

The insulating layer 131 may include traps 160. The traps 160 may exist in both edge regions of the insulating layer 131 that does not overlap the gate electrode 170 in a vertical direction and in the central region of the insulating layer 131 that overlaps the gate electrode 170 in a vertical direction. The traps 160 may vary depending on the type of dopant to be implanted.

As ions accelerated through an ion implantation process are implanted into the insulating layer 131, the traps 160 may be generated by cutting a bonding network of the metal oxide constituting the insulating layer 131. In this case, oxygen released from the metal oxide has free electrons, and as the free electrons diffuse into the 2D material layer 121, the 2D material layer 121 is doped.

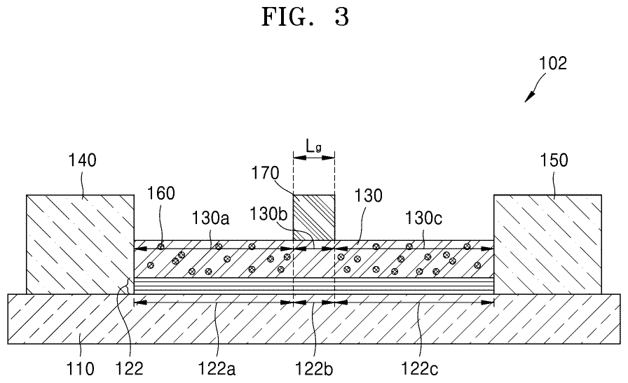

FIG. 3 is a cross-sectional view illustrating a semiconductor device according to another example embodiment.

Referring to FIG. 3, a semiconductor device 102 may include a substrate 110, a two-dimensional (2D) material layer 122 arranged on the substrate 110 and extending in a first direction, a source electrode 140 and a drain electrode 150 electrically connected to the 2D material layer 122, an insulating layer 130 arranged on the 2D material layer 122, and a gate electrode 170 arranged vertically spaced apart from the 2D material layer 122 in a second direction perpendicular to the first direction.

The semiconductor device 102 of FIG. 3 may be the same as the semiconductor device 100 of FIG. 1, except that the 2D material layer 122 is different from the 2D material layer 120 of FIG. 1. In describing FIG. 3, redundant descriptions of FIG. 1 are omitted.

The 2D material layer 122 may include a plurality of layers. Each layer constituting the 2D material layer 122 may have an atomic level thickness. In FIG. 3, the 2D material layer 122 includes four layers, but is not limited thereto. The 2D material layer 122 may include, for example, 1 to 10 layers. The 2D material layer 122 may include, for example, 1 to 5 layers.

The 2D material layer 122 may include edge regions 122a and 122c and a central region 122b provided between the edge regions 122a and 122c. The central region 122b of the 2D material layer may be located in a center portion of the 2D material layer 122. The edge regions 122a and 122c of the 2D material layer may not overlap the gate electrode 170 in a vertical direction, and the central region 122b of the 2D material layer may overlap the gate electrode 170 in a vertical direction.

The edge regions 122a and 122c of the 2D material layer may be doped at a high concentration to exhibit metal characteristics. The central region 122b of the 2D material layer is not doped and may exhibit semiconductor characteristics. The central region 122b of the 2D material layer may operate as a channel. The central region 122b of the 2D material layer may control on/off of the semiconductor device 100.

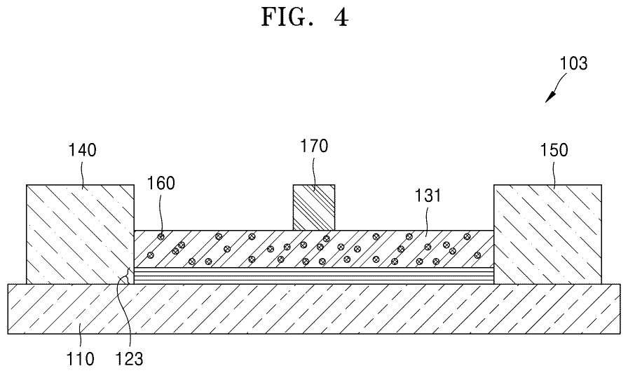

FIG. 4 is a cross-sectional view illustrating a semiconductor device according to another example embodiment.

Referring to FIG. 4, a semiconductor device 103 may include a substrate 110, a two-dimensional (2D) material layer 123 arranged on the substrate 110, and extending in a first direction, a source electrode 140 and a drain electrode 150 electrically connected to the 2D material layer 123, an insulating layer 131 arranged on the 2D material layer 123, and a gate electrode 170 arranged vertically spaced apart from the 2D material layer 123 in a second direction perpendicular to the first direction.

The semiconductor device 103 of FIG. 4 may be the same as the semiconductor device 101 of FIG. 2, except that the 2D material layer 123 is different from the 2D material layer 121 of FIG. 2. In describing FIG. 4, redundant descriptions of FIG. 2 are omitted.

The 2D material layer 123 may include a plurality of layers. Each layer constituting the 2D material layer 123 may have an atomic level thickness. In FIG. 4, the 2D material layer 123 includes four layers, but is not limited thereto. The 2D material layer 123 may include, for example, 1 to 10 layers. The 2D material layer 123 may include, for example, 1 to 5 layers.

The semiconductor devices 100, 101, 102, and 103 respectively shown in FIGS. 1 to 4 may be, for example, a field effect transistor (FET). However, example embodiments are not limited thereto, and the semiconductor devices 100, 101, 102, and 103 respectively shown in FIGS. 1 to 4 may be, for example, a Multi Bridge Channel FET (MBCFET) having a FinFET or a Gate-All-Around (GAA) channel structure.

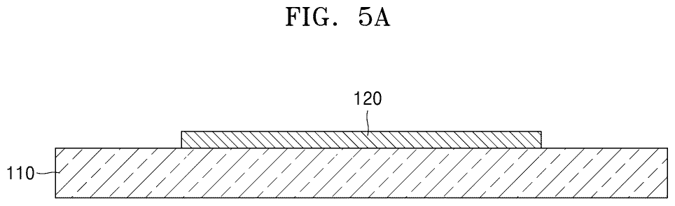

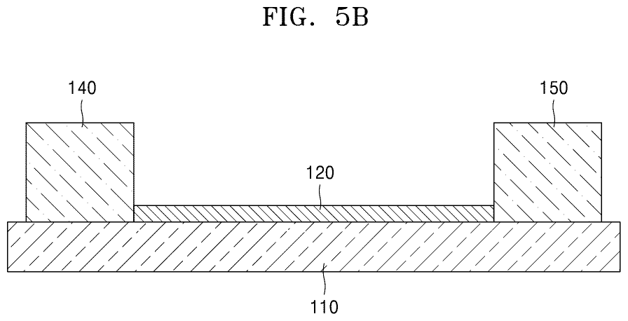

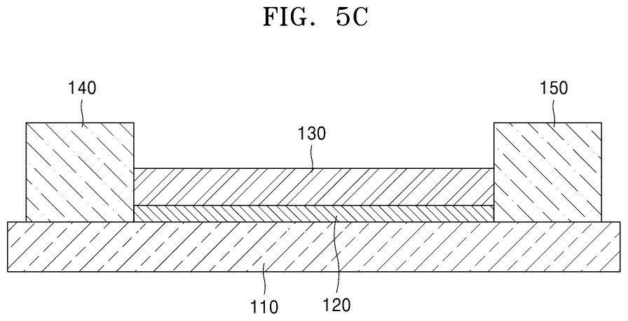

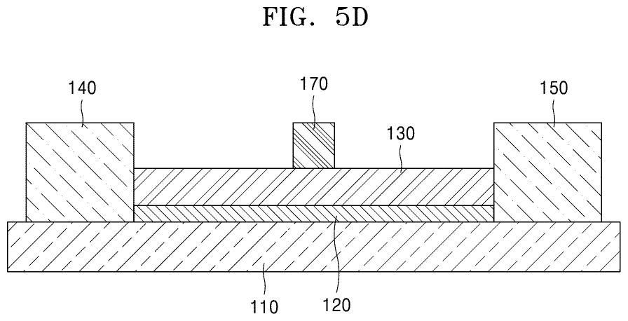

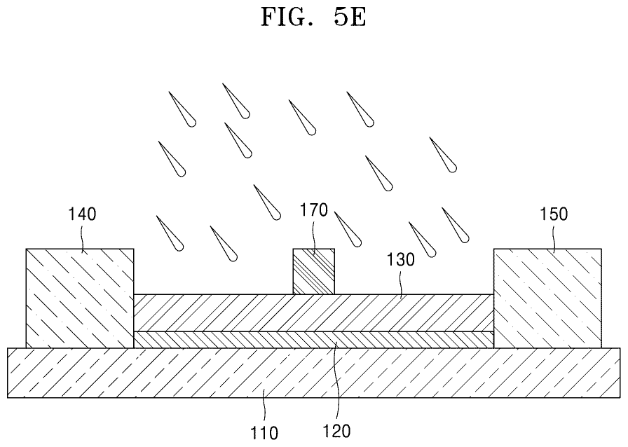

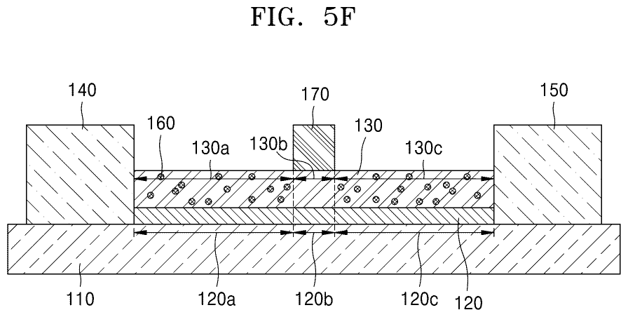

FIGS. 5A to 5F are cross-sectional views illustrating a method of manufacturing a semiconductor device according to an example embodiment. In FIGS. 5A to 5F, the same reference numerals as those in FIG. 1 denote identical members, and a detailed description thereof will be omitted.

Referring to FIG. 5A, a 2D material layer 120 extending in a first direction is formed on a substrate 110. The substrate 110 may include various materials such as a semiconductor material, an insulating material, a metal material, and the like. The 2D material layer 120 may include a 2D semiconductor material. The 2D material layer 120 may include, for example, a transition metal dichalcogenide (TMD).

The 2D material layer 120 may have a single-layer or multi-layer structure, wherein each layer may have an atomic level thickness. The 2D material layer 120 may include, for example, 1 to 10 layers. The 2D material layer 120 may include, for example, 1 to 5 layers. However, the 2D material layer 120 is not limited thereto.

Referring to FIG. 5B, a source electrode 140 and a drain electrode 150 are formed at respective edges of the substrate 110 (e.g., at respective edges of the 2D semiconductor material layer). The source electrode 140 and the drain electrode 150 may be formed by chemical vapor deposition (CVD), physical vapor deposition (PVD), ion implantation and/or diffusion, but methods of forming the source electrode 140 and the drain electrode 150 are not limited thereto.

Referring to FIG. 5C, an insulating layer 130 is formed on a surface of the 2D material layer 120. The insulating layer 130 may include metal oxide. The metal oxide may include at least one metal of Si, Al, La, Ti, Zr, Hf, Mg, Ge, Y, Lu, or Sr.

Referring to FIG. 5D, a gate electrode 170 is formed on the insulating layer 130. The gate electrode 170 may include a metal material or conductive oxide. The gate electrode 170 may be arranged to be spaced apart from the 2D material layer 120 in a second direction perpendicular to the first direction.

Referring to FIG. 5E, a dopant is implanted into the insulating layer 130 by using an ion implantation process. In this case, the gate electrode 170 may function as a mask. Due to the gate electrode 170, the dopant is implanted into both edge regions 130a of the insulating layer 130 that do not overlap the gate electrode 170 in a vertical direction. The dopant may include, for example, P⁺, As⁺, B⁻, Al₋, or H⁺.

Referring to FIG. 5F, traps 160 are formed in the insulating layer 130 into which the dopant is implanted. The traps 160 exist in both edge regions 130a of the insulating layer 130 that do not overlap the gate electrode 170 in a vertical direction. Free electrons from the traps 160 of the insulating layer 130 are diffused into the 2D material layer 120, thereby doping the 2D material layer 120. After the ion implantation process, an operation of annealing the insulating layer 130 may be additionally performed. Through the annealing operation, free electrons from the traps 160 of the insulating layer 130 may be promoted to be diffused into the 2D material layer 120.

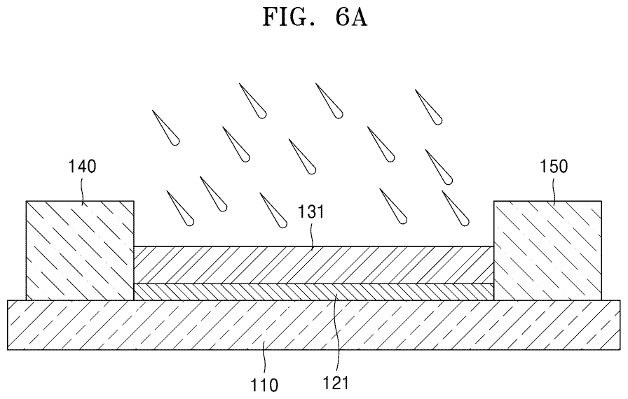

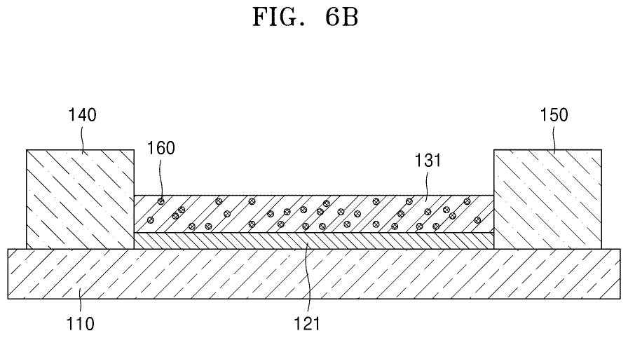

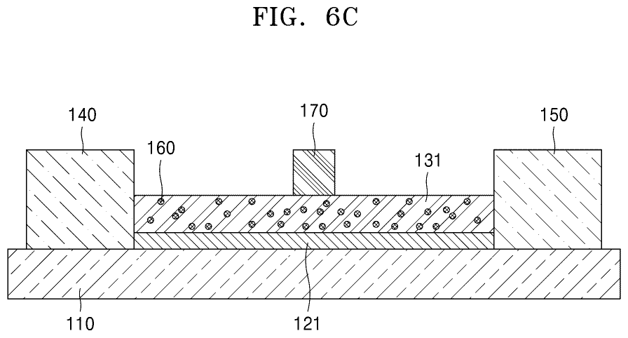

FIGS. 6A to 6C are cross-sectional views partially illustrating a method of manufacturing a semiconductor device according to another example embodiment. In FIGS. 6A to 60, the same reference numerals as those in FIGS. 1 and 2 denote identical members, and a detailed description thereof will be omitted.

Before the processes of FIGS. 6A to 6C, the processes described with reference to FIGS. 5A to 5C may be performed.

Referring to FIG. 6A, a dopant is implanted into the insulating layer 131 by using an ion implantation process. The dopant is uniformly implanted into the entire region of the insulating layer 131. The dopant may include, for example, P⁺, As⁺, B⁻, Al₋, or H⁺.

Referring to FIG. 6B, traps 160 are formed in the insulating layer 131 into which the dopant is implanted. The traps 160 may exist in both edge regions of the insulating layer 131 that does not overlap the gate electrode 170 in a vertical direction and a central region of the insulating layer 131 that overlaps the gate electrode 170 in a vertical direction. Free electrons from the traps 160 of the insulating layer 131 are diffused into the 2D material layer 121 and the 2D material layer 121 is doped.

Referring to FIG. 6C, after the implanting of the dopant into the insulating layer 130, the gate electrode 170 is formed on the insulating layer 130. The gate electrode 170 may include a metal material or conductive oxide.

The method of manufacturing a semiconductor device according to this example embodiment may dope the 2D material layer 120 without causing defects or reducing defects in the 2D material layers 120 and 121 by implanting dopants into the insulating layers 130 and 131 instead of the 2D material layers 120 and 121.

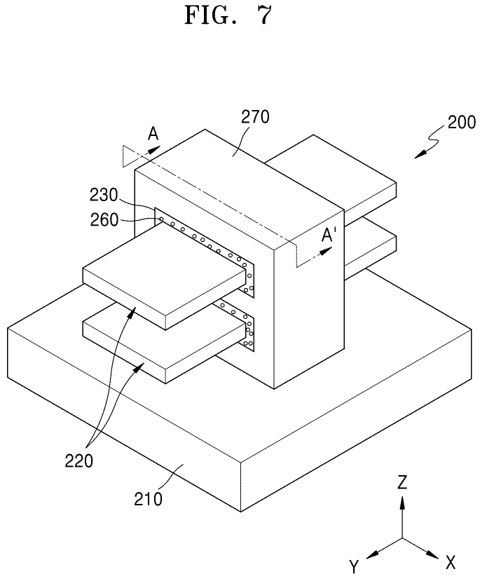

FIG. 7 is a perspective view illustrating a semiconductor device according to another example embodiment.

The semiconductor device 200 may be a multi bridge channel FET (MBCFET) having a gate-all-around (GAA) channel structure. The MBCFET is one type of a GAA transistor structure and has a structure in which a plurality of thin channel layers having a plate shape are vertically stacked, and four surfaces of the plurality of plate-shaped channel layers are formed to be surrounded by the gate electrode.

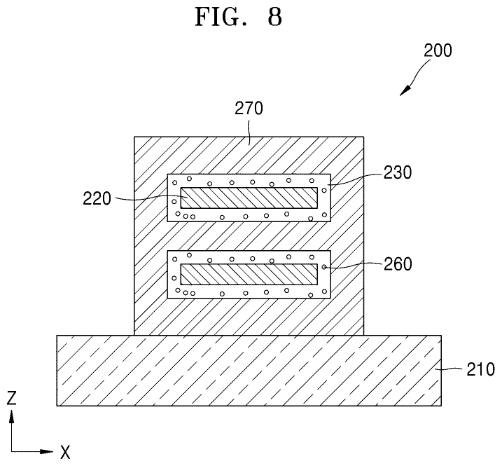

FIG. 8 is a cross-sectional view taken along line A-A′ of FIG. 7.

Referring to FIGS. 7 and 8, at least one channel layer 220 may be arranged on the substrate 210 to be spaced apart from the substrate 210. Here, each channel layer 220 may have a shape of a sheet arranged parallel to the substrate 210. In FIGS. 7 and 8, a case where two channel layers 220 are arranged vertically on an upper portion of the substrate 210 is illustrated as an example.

An insulating layer 230 surrounding the channel layer 220 is provided, and a gate electrode 270 is provided on the gate insulating layer 230. Here, the insulating layer 230 may be provided to surround four surfaces of the channel layer 220, and the gate electrode 270 may be provided to surround four surfaces of the insulating layer 230. Although not shown in the drawings, the source and drain electrodes may be provided on the front and back sides of the channel layer 220, respectively.

The insulating layer 230 may include a dopant. The dopant may be implanted into the insulating layer 230 through an ion implantation process. The dopant may include P⁺, As⁺, B⁻, Al₋, or H⁺.

The insulating layer 230 may include traps 260. As ions accelerated through an ion implantation process are implanted into the insulating layer 230, the traps 260 may be generated by cutting a bonding network of the metal oxide constituting the insulating layer 230. In this case, oxygen released from the metal oxide has free electrons, and the channel layer 220 is doped as the free electrons diffuse to the channel layer 220.

The semiconductor device 200 of FIGS. 7 and 8 is illustrated to exhibit an MBCFET structure, but example embodiments are not limited thereto. The semiconductor device 200 may include a field effect transistor having a Fin channel structure or a planar structure.

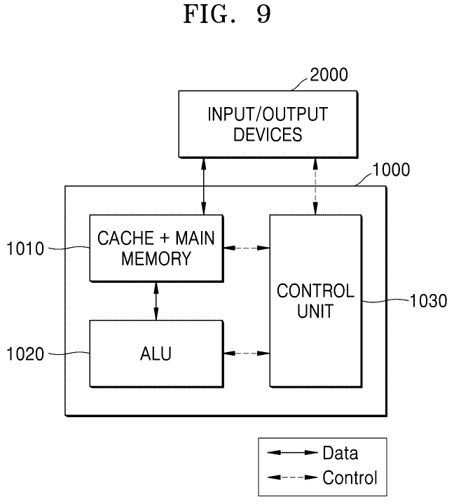

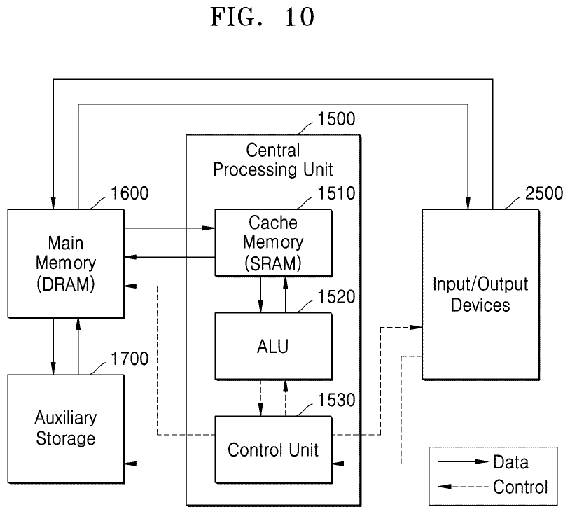

FIGS. 9 and 10 are conceptual block diagrams schematically illustrating an electronic device architecture applicable to an electronic device according to an example embodiment.

Referring to FIG. 9, an electronic device architecture 1000 may include a memory unit 1010, an arithmetic logic unit (ALU) 1020, and a control unit 1030. The memory unit 1010, the ALU 1020, and the control unit 1030 may be electrically connected to each other. For example, the electronic device architecture 1000 may be implemented as a single chip including the memory unit 1010, the ALU 1020, and the control unit 1030.

For example, the memory unit 1010, the ALU 1020, and the control unit 1030 may be interconnected via metal lines on-chip and directly communicate with each other. The memory unit 1010, the ALU 1020, and the control unit 1030 may be monolithically integrated on one substrate to form one chip. An input/output device 2000 may be connected to the electronic device architecture (chip) 1000.

Each of the ALU 1020 and the control unit 1030 may independently include the semiconductor devices 100, 101, 102, 103 and 200 described above, and the memory unit 1010 may include the semiconductor devices 100, 101, 102, 103 and 200, a capacitor, or a combination thereof. The memory unit 1010 may include both a main memory and a cache memory. The electronic device architecture 1000 may be an on-chip memory processing unit.

Referring to FIG. 10, a cache memory 1510, an ALU 1520, and a control unit 1530 may constitute a central processing unit (CPU) 1500. The cache memory 1510 may be formed of a static random access memory (SRAM), and may include the semiconductor devices 100, 101, 102, 103 and 200 described above. Apart from the CPU 1500, a main memory 1600 and an auxiliary storage 1700 may be provided. The main memory 1600 may include a dynamic random access memory (DRAM) device. An input/output device 2500 may be connected to the control unit 1530.

In some cases, the electronic device architecture may be implemented in a form in which computing unit elements and memory unit elements are adjacent to each other in one chip without division of sub-units.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

According to the semiconductor devices of the present disclosure and the manufacturing methods thereof, by implanting a dopant into an insulating layer rather than a 2D material layer, a 2D material layer may be doped without causing defects or reducing defects in the 2D material layer. The semiconductor devices and the methods of manufacturing the same according to some example embodiments have been described with reference to embodiments shown in the drawings. According to the example disclosed embodiments, the method of manufacturing a semiconductor device may perform 2D material channel doping without causing defects or reducing defects in the 2D material channel by performing ion implantation into an insulating layer of a 2D material.

According to the disclosed example embodiments, the methods of manufacturing semiconductor devices may control the threshold voltage of the semiconductor device by controlling the doping level of the 2D material.

It should be understood that some example embodiments described herein should be considered in a descriptive sense only and not for purposes of limitation. Descriptions of features or aspects within each embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A semiconductor device comprising:
a two-dimensional (2D) material layer extending in a first direction;
a source electrode and a drain electrode each electrically connected to the 2D material layer;
an insulating layer on the 2D material layer; and
a gate electrode being apart from the 2D material layer in a second direction perpendicular to the first direction, wherein
the insulating layer includes a dopant.

2. The semiconductor device of claim 1, wherein the dopant is present in both edge regions of the insulating layer that do not overlap the gate electrode in the second direction.

3. The semiconductor device of claim 1, wherein the dopant comprises P⁺, As⁺, B⁻, Al₋, or H⁺.

4. The semiconductor device of claim 1, wherein the insulating layer comprises traps.

5. The semiconductor device of claim 4, wherein the traps are present in both edge regions of the insulating layer that do not overlap the gate electrode in the second direction.

6. The semiconductor device of claim 1, wherein a region of the 2D material layer overlapping the gate electrode in the second direction operates as a channel.

7. The semiconductor device of claim 1, wherein a region of the 2D material layer overlapping the gate electrode in the second direction exhibits semiconductor characteristics.

8. The semiconductor device of claim 1, wherein an edge region of the 2D material layer that does not overlap the gate electrode in the second direction exhibits metal characteristics.

9. The semiconductor device of claim 1, wherein the 2D material layer comprises graphene, transition metal dichalcogenide (TMD), or black phosphorus.

10. The semiconductor device of claim 1, wherein the dopant is uniformly present in an entire region of the insulating layer.

11. The semiconductor device of claim 1, wherein the insulating layer comprises metal oxide.

12. The semiconductor device of claim 11, wherein the metal oxide comprises Si, Al, La, Ti, Zr, Hf, Mg, Ge, Y, Lu, or Sr.

13. The semiconductor device of claim 1, wherein the 2D material layer comprises a plurality of layers.

14. The semiconductor device of claim 1, wherein the gate electrode comprises metal, conductive nitride, or conductive oxide.

15. The semiconductor device of claim 1, wherein a width of the gate electrode is about 10 nm to about 100 nm.

16. The semiconductor device of claim 1, wherein the semiconductor device is a field effect transistor.

17. A method of manufacturing a semiconductor device, the method comprising:
forming a two-dimensional (2D) material layer extending in a first direction on a substrate;
forming a source electrode and a drain electrode on edges of the substrate;
forming an insulating layer on the 2D material layer; and
implanting a dopant into the insulating layer.

18. The method of claim 17, further comprising,
before the implanting, forming a gate electrode on the insulating layer,
wherein the implanting implants the dopant into the insulating layer by using the gate electrode as a mask.

19. The method of claim 17, further comprising,
after the implanting, forming a gate electrode on the insulating layer.

20. The method of claim 17, further comprising,
after the implanting, annealing the insulating layer.
